(19) United States
(12) Patent Application Publication
(10) Pub. No.: US 2024/0213232 A1
(43) Pub. Date: Jun. 27, 2024

(54) Tiling Display Device

(71) Applicant: LG Display Co., Ltd., Seoul (KR)

(72) Inventors: Jaeho Lee, Paju-si (KR); Rokhee Lee, Seoul (KR)

(21) Appl. No.: 18/349,861

(22) Filed: Jul. 10, 2023

(30) Foreign Application Priority Data
Dec. 26, 2022 (KR) 10-2022-0184330

(51) Int. Cl. H01L 25/16; H01L 33/60

(52) U.S. Cl. CPC H01L 25/162; H01L 25/167; H01L 33/60

(57) ABSTRACT

A display device includes a lower substrate having a thin-film transistor disposed thereon; a plurality of upper substrates respectively having light-emitting elements disposed thereon, wherein the plurality of upper substrates are spaced apart from each other and are disposed on the lower substrate; conductive adhesive members disposed between the lower substrate and the upper substrates; a first filling material filling a space between the lower substrate and each of the upper substrates, wherein the first filling material covers the conductive adhesive members; and a second filling material filling a boundary area between adjacent ones of the plurality of upper substrates.

### CROSS-REFERENCE TO RELATED APPLICATION

This application claims priority from Korean Patent Application No. 10-2022-0184330 filed on Dec. 26, 2022 in the Korean Intellectual Property Office, and all the benefits accruing therefrom under 35 U.S.C. 119, the contents of which in its entirety are herein incorporated by reference.

### BACKGROUND

### Field

The present disclosure relates to a display device, and more particularly, to a tiling display device having a simplified structure.

### Description of Related Art

A display device is applied to various electronic devices such as TVs, mobile phones, laptops, and tablets. To this end, research to develop thinning, lightening, and low power consumption of the display device is continuing.

Among display devices, a light-emitting display device has a light-emitting element or a light source built therein and displays information using light generated from the built-in light-emitting element or light source. A display device including a self-light-emitting element may be implemented to be thinner than a display device with the built-in light source, and may be implemented as a flexible display device that may be folded, bent, or rolled.

The display device having the self-light-emitting element may include, for example, an organic light-emitting display device (OLED) including a light-emitting layer made of an organic material, or a micro-LED display device (micro light-emitting diode display device) including a light-emitting layer made of an inorganic material. In this regard, the organic light-emitting display device does not require a separate light source. However, due to material characteristics of the organic material that is vulnerable to moisture and oxygen, a defective pixel easily occurs in the organic light-emitting display device due to an external environment. On the contrary, the micro-LED display device includes the light-emitting layer made of the inorganic material that is resistant to moisture and oxygen and thus is not affected by the external environment and thus has high reliability and has a long lifespan compared to the organic light-emitting display device.

### SUMMARY

Since the micro-LED display device is resistant to the external environment, the micro-LED display device does not require a protective structure such as a sealing material, and various types of materials may be used as a material of a substrate of the device, thereby implementing a flexible display device with a thinner structure than that of the organic light-emitting display device. Accordingly, a plurality of micro-LED display devices may be arranged in first and second horizontal directions intersecting each other to implement a large-area tiling display device

When the tiling display device is implemented by arranging a plurality of micro-LED display devices in the first and second horizontal directions intersecting each other, a structure for blocking a non-display area surrounding a display area from the user's field of view, for example, a bezel, is disposed. As a width of the bezel increases, the bezel can be recognized by the user to lower image immersion. Thus, research is being conducted to form a minimum bezel area.

Further, a technical purpose according to an embodiment of the present disclosure is to provide a display device in which a bezel area is minimum or is substantially absent to realize a zero-bezel area.

Further, a purpose according to one embodiment of the present disclosure is to prevent a difference between external light reflection of adjacent panels from occurring to prevent a seam line from being perceived by a viewer.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

An aspect of the present disclosure provides a display device including a lower substrate having a thin-film transistor disposed thereon; a plurality of upper substrates respectively having light-emitting elements disposed thereon, wherein the plurality of upper substrates are spaced apart from each other and are disposed on the lower substrate; conductive adhesive members disposed between the lower substrate and the upper substrates; a first filling material filling a space between the lower substrate and each of the upper substrates, wherein the first filling material covers the conductive adhesive members; and a second filling material filling a boundary area between adjacent ones of the plurality of upper substrates.

In one implementation, the lower substrate is composed of a single substrate, wherein the upper substrates are disposed on the lower substrate and are arranged in a matrix manner and are spaced apart from each other.

In one implementation, the first filling material includes a resin with relatively high viscosity and low flowability.

In one implementation, each of the upper substrates includes a first surface on which the light-emitting element is disposed, and a second surface opposite to the first surface, wherein a vertical height of an uppermost face of the first filling material is lower than a vertical height of the first surface of the upper substrate.

In one implementation, each of the upper substrates includes glass or plastic.

In one implementation, the second filling material has a second refractive index and a second light transmittance respectively substantially equal to a first refractive index and a first light transmittance of each of the upper substrates.

In one implementation, the second refractive index is in a range of 1.45 to 2.0, wherein the second light transmittance in a visible light region is 90% or greater.

In one implementation, the second filling material includes perhydropolysilazane resin.

In one implementation, the lower substrate further has a light-blocking pattern disposed thereon and at a location corresponding to a boundary area between adjacent ones of the upper substrates.

In one implementation, the light-blocking pattern is disposed between the first filling material and the second filling material.

In one implementation, each of the upper substrates includes a first surface on which the light-emitting element is disposed and a second surface opposite to the first surface, wherein a vertical height of an uppermost face of the light-blocking pattern is lower than a vertical height of the first surface of the upper substrate.

In one implementation, the light-emitting element includes: a first semiconductor layer; an active layer disposed on one side of one surface of the first semiconductor layer; a second semiconductor layer disposed on the active layer; a reflective layer disposed on the second semiconductor layer; a first electrode connected to the first semiconductor layer; and a second electrode connected to the reflective layer.

In one implementation, the reflective layer is in contact with an entirety of one surface of the second semiconductor layer.

According to one embodiment of the present disclosure, the display device in which a bezel area is minimum or is substantially absent to realize a zero-bezel area may be provided.

Further, electrically connecting the upper and lower substrates to each other via the conductive adhesive members may allow a side surface line formation process to be omitted, thereby realizing process optimization.

Further, a tiling structure between adjacent panels can be simplified such that a cost reduction is achieved, and an optical seam area is not recognized by the user, and thus the user's image immersion may be improved.

Further, the tiling display device with a structure in which the plurality of upper substrates are disposed on one lower substrate may be realized. The structure of the tiling display device may be simpler than a structure in which the plurality of lower substrates and the plurality of upper substrates are respectively bonded to each other. Thus, a unified structure may be achieved and thus production cost can be saved.

Effects of the present disclosure are not limited to the effects mentioned above, and other effects not mentioned will be clearly understood by those skilled in the art from the descriptions below.

### BRIEF DESCRIPTION OF DRAWINGS

FIG. 1 is a schematic plan view of a tiling display device according to one embodiment of the present disclosure.

FIG. 2 is a cross-sectional view taken alone line 2-2 in FIG. 1.

FIG. 3 is an enlarged view of area 3 in FIG. 2.

FIG. 4 is an enlarged view of a light-emitting element of FIG. 3.

FIG. 5 is a cross-sectional view showing a tiling display device according to another embodiment of the present disclosure.

FIG. 6 is an enlarged view of 6 in FIG. 5.

FIGS. 7 to 11 are diagrams for illustrating a method for manufacturing a tiling display device according to one embodiment of the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc. disclosed in the drawings for describing the embodiments of the present disclosure are exemplary, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology herein is only used for describing specifical embodiments and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device according to each embodiment of the present disclosure will be described with reference to the accompanying drawings.

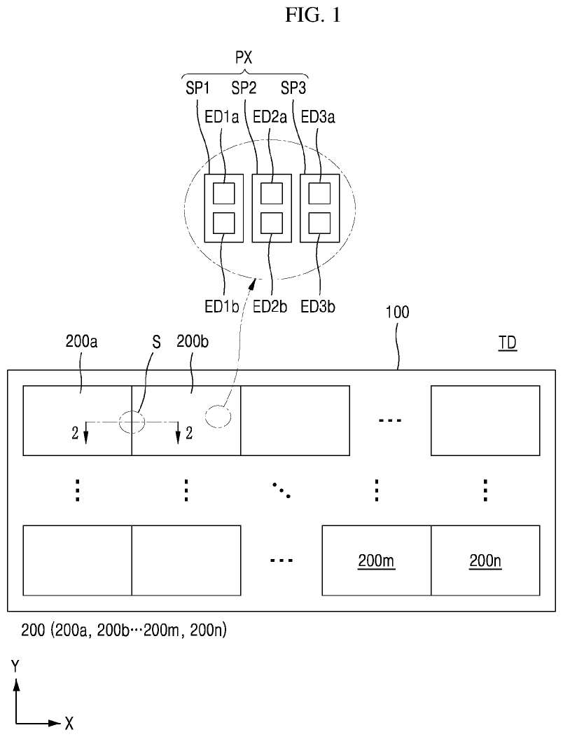

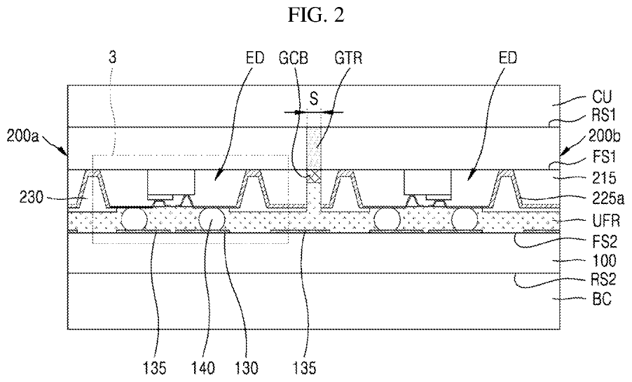

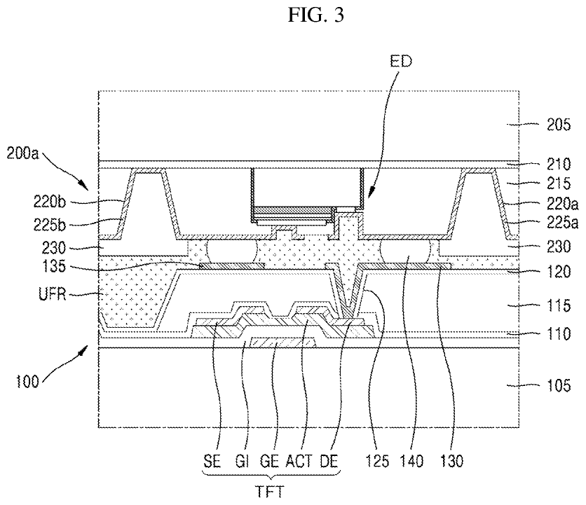

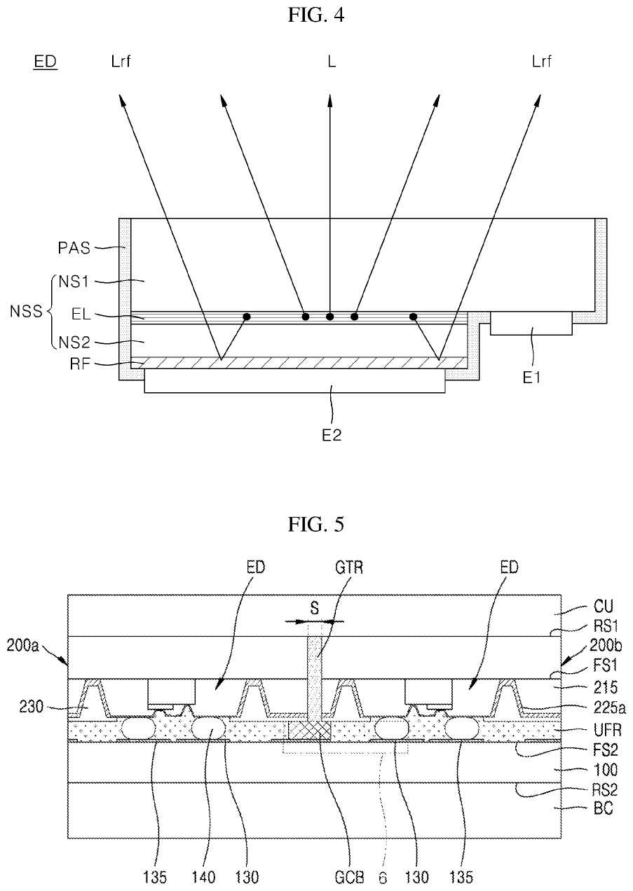

FIG. 1 is a schematic plan view of a tiling display device according to one embodiment of the present disclosure. FIG. 2 is a cross-sectional view taken alone line 2-2 in FIG. 1. FIG. 3 is an enlarged view of area 3 in FIG. 2. FIG. 4 is an enlarged view of a light-emitting element of FIG. 3.

Referring to FIG. 1 to FIG. 4, a tiling display device TD according to one embodiment of the present disclosure may be configured to include one lower substrate 100 and a plurality of upper substrates 200a, 200b . . . 200m and 200n arranged on one lower substrate 100. In this regard, M and N may be natural numbers. The upper substrates 200a, 200b . . . 200m and 200n may be arranged along a first direction X and a second direction Y intersecting the first direction X such that adjacent upper substrates contact each other. In this regard, the first direction X may be a longitudinal direction, and the second direction Y may be a transverse direction.

A plurality of pixels PX may be disposed in each of the plurality of upper substrates 200a, 200b . . . 200m and 200n. Each of the plurality of pixels PX may include a plurality of sub-pixels SP1, SP2, and SP3. Each of the plurality of sub-pixels SP1, SP2, and SP3 may include at least one light-emitting element ED1a, ED2a, and ED3a. For example, the light-emitting elements ED1a, ED2a, and ED3a may include the first light-emitting element ED1a, the second light-emitting element ED2a, and the third light-emitting element ED3a emitting red (R), green (G), and blue (B) light, respectively. Further, each of the plurality of sub-pixels SP1, SP2, and SP3 may further include redundant light-emitting elements ED1b, ED2b, and ED3b for a repair process. For example, the redundant light-emitting elements ED1b, ED2b, and ED3b may include the first redundant light-emitting element ED1b corresponding to the first light-emitting element ED1a, the second redundant light-emitting element ED2b corresponding to the second light-emitting element ED2a and the third redundant light-emitting element ED3b corresponding to the third light-emitting element ED3a. Further, in an embodiment of the present disclosure, the light-emitting elements emitting light of red (R), green (G), and blue (B) colors, respectively are described. However, the present disclosure is not limited thereto, and the light-emitting element may further include a light-emitting element which emits white light. The light-emitting element according to an embodiment of the present disclosure may be embodied as a micro-LED. The micro-LED may be a LED made of an inorganic material, and may refer to a light-emitting element with a thickness of 100 μm or smaller or free of a growth substrate for growing the LED.

In one example, when the tiling display device TD is implemented by connecting the plurality of upper substrates 200a, 200b . . . , 200m and 200n with each other so as to be in contact with each other, a spacing between the outermost pixel PX of one upper substrate and the outermost pixel PX of another upper substrate adjacent thereto may be equal to a spacing between adjacent pixels of a single upper substrate. Accordingly, the bezel area may be minimum or may be implemented as a zero-bezel area in which a bezel area size is substantially absent.

When a space occupied by the bezel area is minimized, and thus the display area increases, the user recognizes that an image is continuous in a seamless manner, such that the user's screen immersion may increase. Accordingly, schemes for minimizing the space occupied by the bezel area are being studied.

In one of the schemes for minimizing the space occupied by the bezel area, a seam area S as a boundary area between the adjacent ones of the upper substrates 200a, 200b . . . 200m and 200n is not recognized by the user.

Referring to FIG. 2, the upper substrates 200a and 200b are arranged on the lower substrate 100. The upper substrates 200a and 200b may include the first upper substrate 200a and the second upper substrate 200b. In the drawings, for convenience of illustration, only a configuration in which two upper substrates 200a and 200b are disposed is presented. However, the present disclosure is not limited thereto. For example, another upper substrate may be disposed adjacent to one side of each of the upper substrates 200a and 200b.

A light-emitting element ED may be disposed on each of the first and second upper substrates 200a and 200b according to an embodiment of the present disclosure. The light-emitting element ED may be disposed on a first surface FS1 of each of the first and second upper substrates 200a and 200b. Here, the first surface FS1 may be a lower surface of the first and second upper substrates 200a and 200b. Further, a thin-film transistor TFT for driving the light-emitting element ED may be disposed on the lower substrate 100. For example, the thin-film transistor TFT may be disposed on an upper surface of the lower substrate 100. In addition, connection members electrically connecting the light-emitting element ED and the thin-film transistor TFT to each other may be disposed on the lower substrate 100. For example, connection members may be connection electrodes 130 and 135 electrically connecting the light-emitting element ED and the thin-film transistor TFT to each other. However, the present disclosure is not limited to it. Other connection members in the prior art may also be used. For example, the connection member may also be connection wires or connection patterns formed of conductive materials.

Each of the first upper substrate 200a and the second upper substrate 200b may be bonded and connected to the connection electrodes 130 and 135 on the lower substrate 100 via conductive adhesive members 140, respectively. A space between the upper substrates 200a and 200b and the lower substrate 100 may be filled with a first filling material UFR. The first filling material UFR may include a non-flowable resin with relatively high viscosity and low flowability. The first filling material UFR may extend upwardly to a position lower than a first surface FS1 of each of the upper substrates 200a and 200b.

The seam area S as a boundary area between the first upper substrate 200a and the second upper substrate 200b may be filled with a second filling material GTR having a refractive index similar to that of a material constituting each of the first and second upper substrates 200a and 200b. For example, each of the first and second upper substrates 200a and 200b may include a transparent material such as glass or plastic. In this case, the second filling material GTR may include a transparent material. The second filling material GTR may include a material having a refractive index in a range of 1.45 to 2.0 which is a range of a refractive index n of glass constituting the first and second upper substrate 200a and 200b. For example, the second filling material GTR may include a material having a refractive index of 1.5. Further, the second filling material GTR may have an optical transmittance of 90% or greater in a visible light range. For example, the second filling material GTR may include perhydropolysilazane resin. The perhydropolysilazane may include a hydrogen (H) substituent in polysilazane composed of silicon-nitrogen (Si—N).

In one embodiment of the present disclosure, an example in which the second filling material GTR is made of perhydropolysilazane is described. However, the present disclosure is not limited thereto. For example, the material having a refractive index and transmittance similar to those of the glass may be applied as the second filling material GRT.

The seam area S may be filled with the second filling material GTR which includes a transparent material having a refractive index and light transmittance similar to those of the glass, such that the difference between external light reflection of adjacent upper substrates is prevented from occurring. This may prevent the user from recognizing the seam area S.

A space between the first filling material UFR and the second filling material GTR may be filled with a light-blocking pattern GCB. The light-blocking pattern GCB may be made of an opaque material. The light-blocking pattern GCB may include a material that may block light, for example, such as black ink or carbon black. The light-blocking pattern GCB serves to prevent a circuit disposed on the lower substrate 100 from being visible to the user.

A lower cover BC may be disposed on a second surface RS2 of the lower substrate 100. The lower cover BC may protect elements formed on the lower substrate 100 and the upper substrates 200a and 200b from damage caused by external factors. An upper cover CU may be disposed on a second surface RS1 of each of the upper substrates 200a and 200b.

The upper cover CU may protect the light-emitting element ED from external impact and moisture permeation. The upper cover CU may include glass or plastic. However, the present disclosure is not limited thereto. For example, the upper cover CU may further include a functional optical film such as an anti-scattering film. The upper cover CU may be attached to the upper substrates 200a and 200b via an optical transparent adhesive. However, the present disclosure is not limited thereto. The upper cover CU may be laminated on the upper substrates 200a and 200b to form a single film.

Hereinafter, a description will be made with reference to FIG. 3 as an enlarged view of a portion of an area in which the first upper substrate 200a on which the light-emitting element ED is disposed and the lower substrate 100 on which the thin-film transistor TFT is disposed are bonded to each other.

Referring to FIG. 3, the thin-film transistor TFT driving the light-emitting element ED disposed on the upper substrate 200a is disposed on a base substrate 105 of the lower substrate 100.

The thin-film transistor TFT may include a gate electrode GE formed on the base substrate 105, a semiconductor layer ACT disposed on the gate electrode GE, and a gate insulating layer GI disposed between the semiconductor layer ACT and the gate electrode GE.

The semiconductor layer ACT may include an active area overlapping the gate electrode GE to constitute a channel, and a source area and a drain area at the opposing two sides of the active area. A source electrode SE may be disposed on the source area of the semiconductor layer ACT, and a drain electrode DE may be disposed on the drain area thereof. In one embodiment of the present disclosure, a bottom gate scheme in which the gate electrode GE is disposed below the semiconductor layer ACT is illustrated. However, the present disclosure is not limited thereto. For example, the thin-film transistor TFT may be configured in a top gate scheme in which the gate electrode GE is disposed on top of the semiconductor layer ACT.

An interlayer insulating film 110 is formed on the thin-film transistor TFT. A protective layer 115 may be disposed on the interlayer insulating film 110. The protective layer 115 may have a contact-hole 125 defined therein. The contact-hole 125 may extend through the protective layer 115 so as to expose a portion of a surface of the drain electrode DE. An insulating layer 120 may be disposed on the protective layer 115. The insulating layer 120 may be positioned on the protective layer 115 having the contact-hole 125 defined therein exposing the portion of the surface of the drain electrode DE.

The connection electrodes 130 and 135 may be disposed on the insulating layer 120. The connection electrodes 130 and 135 may include the first connection electrode 130 and the second connection electrode 135. The first connection electrode 130 may be connected to the portion of the drain electrode DE exposed through the contact-hole 125 and may extend along and on a portion of an upper surface of the insulating layer 120. The first connection electrode 130 and the second connection electrode 135 may be spaced apart from each other.

The first upper substrate 200a on which the light-emitting element ED is disposed may face the lower substrate 100 on which the thin-film transistor TFT is disposed. An adhesive layer 210 may be disposed on a base substrate 200 of the first upper substrate 200a. The light-emitting element ED may be attached to the adhesive layer 210. A specific structure of the light-emitting element ED will be described later with reference to FIG. 4.

A planarization layer 215 surrounding the light-emitting element ED may be disposed. The planarization layer 215 may have a first contact-hole 220a and a second contact-hole 220b defined therein and respectively disposed on both opposing sides of the light-emitting element ED interposed therebetween.

A first electrode 225a and a second electrode 225b may be disposed on exposed surfaces of the first contact-hole 220a and the second contact-hole 220b, respectively. The first electrode 225a and the second electrode 225b of the first upper substrate 200a may be electrically connected to the first connection electrode 130 and the second connection electrode 135 of the lower substrate 100 via the conductive adhesive members 140, respectively. For example, the first electrode 225a of the first upper substrate 200a may be connected to the drain electrode DE of the thin-film transistor TFT via the first connection electrode 130. Further, the second electrode 225b of the first upper substrate 200b may be connected to the second connection electrode 135.

The conductive adhesive member 140 may include, for example, a solder paste, an anisotropic conductive film (ACF) or solder ball. The first electrode 225a and the second electrode 225b may be made of the same material. In one example, the first electrode 225a or the second electrode 225b may include a transparent metal oxide such as indium-tin-oxide (ITO) or indium-zinc-oxide (IZO).

A bank 230 may be disposed on the planarization layer 215. The bank 230 may include an opaque material. However, the present disclosure is not limited thereto. In one example, the first contact-hole 220a and the second contact-hole 220b on which the first electrode 225a and the second electrode 225b have been respectively disposed may be filled with a material constituting the bank 230.

A space between the first upper substrate 200a on which the light-emitting element ED is disposed and the lower substrate 100 on which the thin-film transistor TFT is disposed may be filled with the first filling material UFR.

The first filling material UFR may include a resin material with relatively high viscosity and low flowability. For example, the first filling material UFR may be composed of a base resin, a reducing agent, a curing agent, a catalyst and an additive. The base resin may include epoxy. The reducing agent may remove an oxide film of the conductive adhesive member 140. The reducing agent performs a curing reaction of epoxy. The curing agent induces a chemical curing reaction of the epoxy, and the catalyst may control a curing speed of the epoxy.

The light-emitting element ED according to one embodiment of the present disclosure may be embodied as a micro-LED. Further, in an embodiment of the present disclosure, a horizontal or lateral micro-LED is illustrated by way of example. However, the present disclosure is not limited thereto. For example, the light-emitting element may be embodied as a micro-LED with a vertical structure or a micro-LED with a flip-chip structure. Hereinafter, a description will be made with reference to FIG. 4 showing the structure of the light-emitting element ED.

Referring to FIG. 4, the light-emitting element ED may include a nitride semiconductor structure NSS, a passivation pattern PAS, a first electrode E1 and a second electrode E2. The nitride semiconductor structure NSS may include a first semiconductor layer NS1, an active layer EL disposed on one side of one surface of the first semiconductor layer NS1, a second semiconductor layer NS2 disposed on the active layer EL, and a reflective layer RF disposed on the second semiconductor layer NS2.

The passivation pattern PAS may cover an outer side surface of the nitride semiconductor structure NSS. The first electrode E1 is connected to and disposed on the first semiconductor layer NS1, and the second electrode E2 is disposed to be connected to the reflective layer RF.

The first semiconductor layer NS1 may be a layer for supplying electrons to the active layer EL, and may include a nitride semiconductor containing an N-type impurity. The nitride semiconductor may include a GaN-based semiconductor material including GaN, AlGaN, InGaN, or AlInGaN. The N-type impurity may include silicon (Si), germanium (Ge), selenium (Se), tellurium (Te), or carbon (C). However, the present disclosure is not limited thereto.

The active layer EL disposed on one side of one surface of the first semiconductor layer NS1 may be a layer for emitting light based on combination of electrons and holes. The active layer EL may have a multi-quantum well (MQW) structure having a well layer and a barrier layer having a higher band gap than that of the well layer. For example, the active layer EL may include an InGaN layer as the well layer and an AlGaN layer as the barrier layer. However, the present disclosure is not limited thereto.

The second semiconductor layer NS2 may be a layer for injecting holes into the active layer EL. The second semiconductor layer NS2 may include a nitride semiconductor containing a P type impurity. The nitride semiconductor may include a GaN-based semiconductor material including GaN, AlGaN, InGaN, or AlInGaN. The P-type impurity may include manganese (Mg), zinc (Zn), or beryllium (Be).

In an embodiment of the present disclosure, an example in which the first semiconductor layer NS1 and the second semiconductor layer NS2 are made of the nitride semiconductor containing the N-type impurities and the nitride semiconductor containing the P-type impurities, respectively, is described. However, the present disclosure is not limited thereto. In another example, the first semiconductor layer NS1 and the second semiconductor layer NS2 may be made of the nitride semiconductor containing the P-type impurity and the nitride semiconductor containing the N-type impurity, respectively.

Light beams L and Lrf emitted from the light-emitting element ED may include the first light beam L and the second light beam Lrf directed toward the first semiconductor layer NS1. The second light beam Lrf may be a reflected light beam reflected from the reflective layer RF.

The reflective layer RF may be disposed on the second semiconductor layer NS2 and may serve to reflect the light beam emitted toward the second semiconductor layer NS2 among the light beams emitted from the light-emitting element ED toward a light-emitting area, that is, toward the first semiconductor layer NS1. Accordingly, light-emitting efficiency may be increased by increasing an amount of light emitted toward the light-emitting area. The reflective layer RF may be positioned on an entirety of one surface of the second semiconductor layer NS. Accordingly, the reflective layer RF may prevent light emitted toward the second semiconductor layer from being outputted out of the light-emitting element ED.

The reflective layer RF may include a metal material with high reflectivity. For example, the metal material with high reflectivity may have a single-layer structure or a stack structure made of any one material selected from aluminum (Al), copper (Cu), silver (Ag), molybdenum (Mo), gold (Au), magnesium (Mg), calcium (Ca), or barium (Ba), or an alloy of at least two thereof. In this case, as the reflective layer RF should reflect the light emitted from the light-emitting element ED therefrom, the transparent metal oxide such as indium-tin-oxide (ITO) or indium-zinc-oxide (IZO) which has a relatively lower reflectance than that of the metal material is excluded as the material of the reflective layer RF.

Referring to FIG. 3 and FIG. 4, in the light-emitting element ED according to one embodiment of the present disclosure, the reflective layer RF is disposed on the second semiconductor layer NS2, so that the light may be emitted to the outside through the second surface RS1 opposite to the first surface FS1 of the upper substrate 200a.

According to one embodiment of the present disclosure, the seam area S may be filled with the second filling material GTR which includes a transparent material having a refractive index and light transmittance similar to those of the glass, such that the difference between external light reflection of adjacent upper substrates is prevented from occurring. This may prevent the user from recognizing the seam area S. Accordingly, the quality of the product may be improved.

Further, a circuit element such as the thin-film transistor to drive the light-emitting element is disposed on the lower substrate. The upper and lower substrates may be electrically connected to each other via the conductive adhesive member.

Conventionally, a plurality of lower substrates and a plurality of upper substrates are respectively bonded to each other to constitute a plurality of display modules. The plurality of display modules may be arranged in first and second horizontal directions intersecting each other. Thus, the display device may be manufactured. However, this display device requires side surface lines to electrically connect the plurality of lower substrates and the plurality of upper substrates to each other. In this case, each of the plurality of display modules requires a source printed circuit board (hereinafter referred to as S-PCB), and a gate printed circuit board (hereinafter referred to as G-PCB). Thus, the number of process steps and the number of parts increase. For example, when M display modules and N display modules are arranged in a matrix manner of MxN (where each of N and M is a natural number)S-PCBs and G-PCBs are required.

However, in an embodiment of the present disclosure, the plurality of upper substrates are arranged on one lower substrate and the upper substrates and the lower substrate are bonded to and electrically connected to each other via the conductive adhesive members. Thus, the side surface line is not required.

In other words, a plurality of processes for forming the side surface lines extending from the edges of the upper substrates to the edges of the lower substrates in order to electrically connect the plurality of upper and lower substrates to each other may be omitted, thereby realizing process optimization. For example, an edge grinding process for grinding the edge of the upper substrate using a griding wheel, and a process for forming the side surface lines extending from the edges of the upper substrates to the edges of the lower substrates so as to be electrically connected to the S-PCB or G-PCB may be omitted.

Further, conventionally, the plurality of lower substrates and a plurality of upper substrates are respectively bonded to each other to constitute a plurality of display modules. The plurality of display modules may be arranged in first and second horizontal directions intersecting each other. Thus, the display device may be manufactured. However, this display device requires MxN (where each of N and M is a natural number)S-PCBs and G-PCBs. However, in an embodiment of the present disclosure, the plurality of upper substrates are arranged on one lower substrate and the upper substrates and the lower substrate are bonded to and electrically connected to each other via the conductive adhesive members. Thus, two to four S-PCBs may be required, and G-PCBs may not be disposed. Accordingly, process optimization may be realized because the process for forming the G-PCB may be omitted.

Further, a tiling display device with a structure in which the plurality of upper substrates are disposed on one lower substrate may be realized. The structure of the tiling display device may be simpler than a structure in which the plurality of lower substrates and the plurality of upper substrates are respectively bonded to each other. Thus, production cost can be saved.

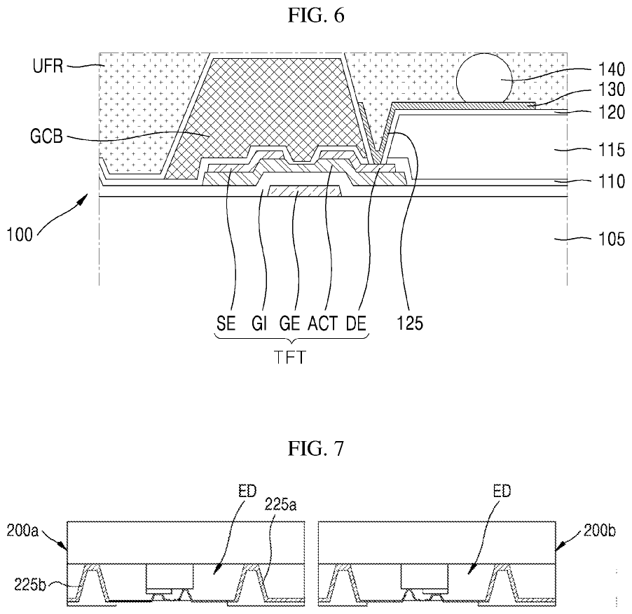

FIG. 5 is a cross-sectional view showing a tiling display device according to another embodiment of the present disclosure. FIG. 6 is an enlarged view of 6 in FIG. 5. The tiling display device according to another embodiment of the present disclosure is the same as the tiling display device according to FIG. 2 except for the second filling material and the light-blocking pattern. Thus, differences are mainly described below, and the same components may be briefly described or description thereof will be omitted.

Referring to FIG. 5 and FIG. 6, the upper substrates 200a and 200b are arranged on the lower substrate 100. The upper substrates 200a and 200b may include the first upper substrate 200a and the second upper substrate 200b.

The light-emitting element ED may be disposed on each of the first and second upper substrates 200a and 200b. The light-emitting element ED may be disposed on the first surface FS1 of each of the first and second upper substrates 200a and 200b. The thin-film transistor TFT for driving the light-emitting element ED and the connection electrodes 130 and 135 electrically connecting the light-emitting element ED and the thin-film transistor TFT to each other may be disposed on the lower substrate 100.

Each of the first upper substrate 200a and the second upper substrate 200b may be bonded and electrically connected to the connection electrodes 130 and 135 on the lower substrate 100 via the conductive adhesive members 140, respectively.

The space between the upper substrates 200a and 200b and the lower substrate 100 may be filled with the first filling material UFR. The first filling material UFR may include a non-flowable resin with relatively high viscosity and low flowability.

The seam area S as a boundary area between the first upper substrate 200a and the second upper substrate 200b may be filled with the second filling material GTR having a refractive index similar to that of a material constituting each of the first and second upper substrates 200a and 200b. For example, each of the first and second upper substrates 200a and 200b may include a transparent material such as glass or plastic. In this case, the second filling material GTR may include a transparent material. The second filling material GTR may include a material having a refractive index in a range of 1.45 to 2.0 which is a range of a refractive index n of glass. For example, the second filling material GTR may include a material having a refractive index of 1.5. Further, the second filling material GTR may have an optical transmittance of 90% or greater in a visible light range. For example, the second filling material GTR may include perhydropolysilazane resin.

The seam area S may be filled with the second filling material GTR which includes a transparent material having a refractive index and light transmittance similar to those of the glass, such that the difference between external light reflection of adjacent upper substrates is prevented from occurring. This may prevent the user from recognizing the seam area S.

The light-blocking pattern GCB may be disposed on the lower substrate 100 and in a space between the first upper substrate 200a and the second upper substrate 200b. The light-blocking pattern GCB may include an opaque material.

Referring to FIG. 6 as an enlarged view of a portion of an area of the lower substrate 100 on which the light-blocking pattern GCB is disposed, the thin-film transistor TFT for driving the light-emitting element ED disposed on the upper substrate 200a is disposed on the base substrate 105 of the lower substrate 100. The thin-film transistor TFT may include a gate electrode GE formed on the base substrate 105, the semiconductor layer ACT disposed on the gate electrode GE, and the gate insulating layer GI disposed between the semiconductor layer ACT and the gate electrode GE. The source electrode SE may be disposed on the source area of the semiconductor layer ACT, and the drain electrode DE may be disposed on the drain area thereof.

The interlayer insulating film 110 is formed on the thin-film transistor TFT. The protective layer 115 may be disposed on the interlayer insulating film 110. The protective layer 115 may have the contact-hole 125 defined therein. The contact-hole 125 may extend through the protective layer 115 so as to expose a portion of a surface of the drain electrode DE. The insulating layer 120 may be disposed on the protective layer 115. The insulating layer 120 may be positioned on the protective layer 115 having the contact-hole 125 defined therein exposing the portion of the surface of the drain electrode DE.

The thin-film transistor TFT may be covered with the light-blocking pattern GCB except for the portion of the drain electrode DE as exposed through the contact-hole 125. The light-blocking pattern GCB may include a light-blocking material that may block light. For example, the light-blocking material may include black ink or carbon black. The light-blocking pattern GCB prevents the circuit element such as the thin-film transistor TFT disposed on the lower substrate 100 from being visible to the user.

The lower cover BC may be disposed on the second surface RS2 of the lower substrate 100 facing the first surface FS2 thereof. The upper cover CU may be disposed on the second surface RS1 of each of the upper substrates 200a and 200b. The upper cover CU may protect the light-emitting element ED from external impact and moisture permeation. The upper cover CU may include glass or plastic. However, the present disclosure is not limited thereto. For example, the upper cover CU may further include a functional optical film such as an anti-scattering film.

FIGS. 7 to 11 are diagrams for illustrating a method for manufacturing a tiling display device according to one embodiment of the present disclosure.

Referring to FIG. 7, a plurality of upper substrates 200a and 200b, each having the light-emitting element ED disposed thereon, are prepared. Since the light-emitting element ED disposed on each of the upper substrates 200a and 200b has the same configuration as that of the light-emitting element ED according to FIGS. 3 and 4, descriptions thereof may be omitted. Only the light-emitting element ED, and the first electrode 225a and the second electrode 225b for subsequent connection to the thin-film transistor may be disposed on each of the upper substrates 200a and 220b. The thin-film transistor may not be disposed on each of the upper substrates 200a and 220b. Each of the upper substrate 200a and 200b may include a transparent material such as glass or plastic.

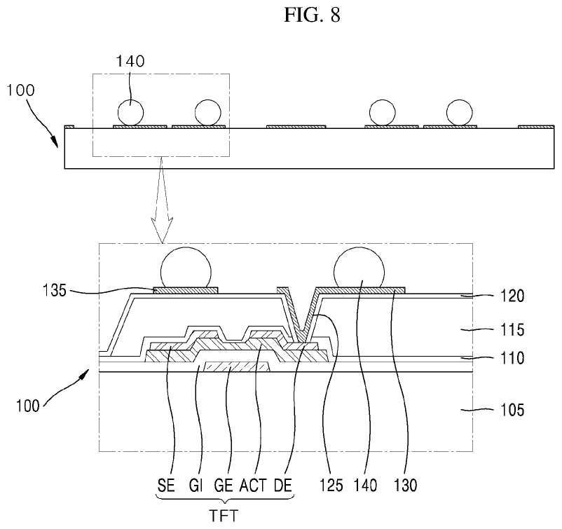

Referring to FIG. 8, the lower substrate 100 on which the thin-film transistor TFT is disposed is provided. Since the configuration of the thin-film transistor TFT disposed on the lower substrate 100 is identical to the configuration of the thin-film transistor TFT according to FIG. 3, the description thereof may be omitted. The thin-film transistor TFT may include the gate electrode GE formed on the base substrate 105, the semiconductor layer ACT disposed on the gate electrode GE, and the gate insulating layer GI disposed between the semiconductor layer ACT and the gate electrode GE. The source electrode SE may be disposed on the source area of the semiconductor layer ACT, and the drain electrode DE may be disposed on the drain area thereof. In one embodiment of the present disclosure, a bottom gate scheme in which the gate electrode GE is located below the semiconductor layer ACT is illustrated. However, the present disclosure is not limited thereto. For example, the thin-film transistor TFT may be configured in a top gate scheme in which the gate electrode GE is located on top of the semiconductor layer ACT.

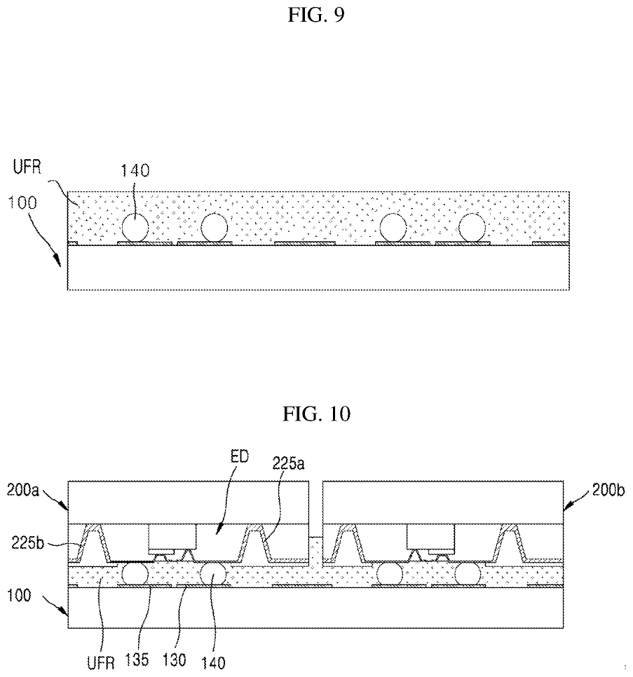

Referring to FIG. 9, the first filling material UFR is supplied and placed on the lower substrate 100. The first filling material UFR may be placed using an underfill process. The first filling material UFR may include a resin material with relatively high viscosity and low flowability. For example, the first filling material UFR may be composed of a base resin, a reducing agent, a curing agent, a catalyst and an additive. The base resin may include epoxy. In this regard, the flowability of the base resin may be lowered by adjusting the viscosity of the epoxy. The reducing agent may remove an oxide film of the conductive adhesive member 140. The reducing agent performs a curing reaction of epoxy. The curing agent induces a chemical curing reaction of the epoxy, and the catalyst may control a curing speed of the epoxy.

The underfill process may include a scheme of filling the space with a liquid resin having a relatively low viscosity or a scheme of filling the space with a resin having a relatively high viscosity and no flowability. The scheme using the resin having fluidity may fill the space using a capillary phenomenon. However, this scheme may cause a problem in that an empty space occurs in filling a space having a large area.

However, the viscosity of the resin having no flowability is relatively high, and thus the resin can be aligned with the space to be filled therewith. The resin having no flowability can advantageously fill a space with a large area. Accordingly, in an embodiment of the present disclosure, it is preferable to perform an underfill process based on the resin having relatively high viscosity and no fluidity.

Referring to FIG. 10, the plurality of upper substrates 200a and 200b are bonded onto the lower substrate 100. The plurality of upper substrates 200a and 200b on which the light-emitting elements ED are respectively disposed are disposed are placed on the lower substrate 100 on which thin-film transistor TFT is disposed. In the drawings, for convenience of illustration, only the first upper substrate 200a and the second upper substrate 200b are presented. However, the present disclosure is not limited thereto. For example, as shown in FIG. 1, the upper substrates may be spaced apart from each other and may be arranged in the matrix form.

Each of the upper substrates 200a and 200b may be connected to the lower substrate 100 using a plurality of conductive adhesive members 140 in a bonding process. The plurality of conductive adhesive members 140 may be disposed on the first connection electrode 130 and the second connection electrode 135, respectively.

The bonding process using the conductive adhesive member 140 may include, for example, one selected from a scheme of printing a solder paste and reflowing the same at a high temperature, a scheme of placing an anisotropic conductive film (ACF) and thermally compressing the same, and a scheme of placing a solder ball and reflowing the same at a high temperature.

Then, as shown in FIG. 3, the first electrode 225a of the first upper substrate 200a may be connected to the drain electrode DE of the thin-film transistor TFT via the first connection electrode 130. Further, the second electrode 225b of the first upper substrate 200b may be connected to the second connection electrode 135.

Heat may be applied to cure the first filling material UFR to fix the plurality of upper substrates 200a and 200b onto the lower substrate 100.

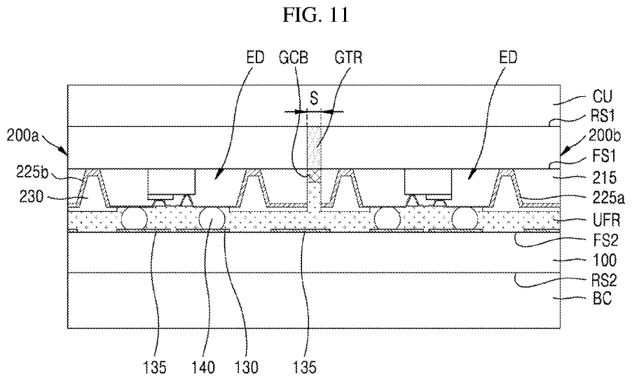

Referring to FIG. 11, the second filling material GTR may be formed to fill the seam area S as the boundary between the first upper substrate 200a and the second upper substrate 200b.

To this end, first, the light-blocking pattern GCB that prevents the circuit patterns including the connection electrodes 130 and 135 disposed on the lower substrate 100 from being recognized by the user may be formed. The light-blocking pattern GCB may be formed to have a thickness so as to fill a portion of the seam area S. In one example, a top face of the light-blocking pattern GCB may be coplanar with the first surface FS1 of each of the upper substrates 200a and 200b. The light-blocking pattern GCB may include an opaque material, such as black ink or carbon black. When the thickness of the light-blocking pattern GCB is sized such that the vertical height of the top face of the light-blocking pattern is higher than that of the first surface FS1 of each of the upper substrates 200a and 200b, for example, the top face of the light-blocking pattern is closer to the second surface RS1 of each of the upper substrates 200a and 200b than the first surface FS1 of each of the upper substrates 200a and 200b is, the light-blocking pattern GCB can be recognized by the user due to the material characteristics of the light-blocking pattern GCB composed of the opaque material, such that the quality of the image may deteriorate. Therefore, it is preferable to form the light-blocking pattern GCB so as to have a thickness that the vertical height of the top face of the light-blocking pattern is lower than that of the first surface FS1 of each of the upper substrates 200a and 200b.

Next, the seam area S as the boundary area between the first upper substrate 200a and the second upper substrate 200b in which the light-blocking pattern GCB is disposed is filled with the second filling material GTR. The second filling material GTR has a refractive index similar to that of a material constituting each of the first and second upper substrates 200a and 200b. For example, each of the first and second upper substrates 200a and 200b may include a transparent material such as glass or plastic. In this case, the second filling material GTR may include a transparent material. The second filling material GTR may include a material having a refractive index in a range of 1.45 to 2.0 which is a range of a refractive index n of glass. For example, the second filling material GTR may include a material having a refractive index of 1.5. Further, the second filling material GTR may have an optical transmittance of 90% or greater in a visible light range. For example, the second filling material GTR may include perhydropolysilazane resin.

Next, the upper cover CU is placed on the upper substrates 200a and 200b, and the lower cover BC is placed on the lower substrate 100. The upper cover CU may protect the light-emitting element ED from external impact. The upper cover CU may further include a functional optical film such as an anti-scattering film. The upper cover CU may be attached to the upper substrates 200a and 200b via an optical transparent adhesive. However, the present disclosure is not limited thereto. The upper cover CU may be laminated on the upper substrates 200a and 200b to form a single film.

According to one embodiment of the present disclosure, the seam area S may be filled with the second filling material GTR which includes a transparent material having a refractive index and light transmittance similar to those of the glass, such that the difference between external light reflection of adjacent upper substrates is prevented from occurring. This may prevent the user from recognizing the seam area S. Thus, the user's image immersion may be improved.

According to one embodiment of the present disclosure, only the light-emitting element excluding the circuit element is disposed on the upper substrate, while the circuit element such as the thin-film transistor is disposed on the lower substrate. Thus, the display device in which a bezel area is minimum or is substantially absent to realize a zero-bezel area may be provided.

Further, the circuit element such as the thin-film transistor to drive the light-emitting element is placed on the lower substrate. The upper and lower substrates may be electrically connected to each other via the conductive adhesive members. Thus, electrically connecting the upper and lower substrates to each other via the conductive adhesive members may allow a side surface line formation process to be omitted, thereby realizing process optimization.

Further, the tiling structure between adjacent panels can be simplified such that a cost reduction is achieved, and an optical seam area is not recognized by the user, and thus the user's image immersion may be improved.

Further, the tiling display device with a structure in which the plurality of upper substrates are disposed on one lower substrate may be realized. The structure of the tiling display device may be simpler than a structure in which the plurality of lower substrates and the plurality of upper substrates are respectively bonded to each other. Thus, a unified structure may be achieved and thus production cost can be saved.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A tiling display device comprising:
a lower substrate having a thin-film transistor disposed thereon;
a plurality of upper substrates respectively having light-emitting elements disposed thereon, wherein the plurality of upper substrates are spaced apart from each other and are disposed on the lower substrate;
conductive adhesive members respectively disposed between the lower substrate and the plurality of upper substrates;
a first filling material filling a space between the lower substrate and each of the plurality of upper substrates, wherein the first filling material covers the conductive adhesive members, and is filled between the lower substrate and each of the plurality of upper substrates; and
a second filling material filling a boundary area between adjacent ones of the plurality of upper substrates.

2. The tiling display device of claim 1, wherein the lower substrate is composed of a single sheet substrate, and wherein the upper substrates are disposed on the lower substrate and are arranged in a matrix form and are spaced apart from each other.

3. The tiling display device of claim 1, wherein the first filling material includes a resin with relatively high viscosity and low flowability.

4. The tiling display device of claim 1, wherein each of the plurality of upper substrates includes a first surface on which the light-emitting element is disposed, and a second surface opposite to the first surface,
wherein a vertical height of an uppermost face of the first filling material is lower than a vertical height of the first surface of the upper substrate.

5. The tiling display device of claim 1, wherein each of the upper substrates includes glass or plastic.

6. The tiling display device of claim 1, wherein the second filling material has a second refractive index and a second light transmittance respectively equal to a first refractive index and a first light transmittance of each of the plurality of upper substrates.

7. The tiling display device of claim 6, wherein the second refractive index is in a range of 1.45 to 2.0, and wherein the second light transmittance in a visible light region is 90% or greater.

8. The tiling display device of claim 6, wherein the second filling material includes perhydropolysilazane resin.

9. The tiling display device of claim 1, further comprises a light-blocking pattern disposed between adjacent ones of the upper substrates.

10. The tiling display device of claim 9, wherein the light-blocking pattern is disposed between the first filling material and the second filling material.

11. The tiling display device of claim 9, wherein each of the upper substrates includes a first surface on which the light-emitting element is disposed and a second surface opposite to the first surface, and
wherein a vertical height of an uppermost face of the light-blocking pattern is lower than a vertical height of the first surface of the upper substrate.

12. The tiling display device of claim 1, wherein the light-emitting element includes:
a first semiconductor layer;
an active layer disposed on one side of one surface of the first semiconductor layer;
a second semiconductor layer disposed on the active layer;
a reflective layer disposed on the second semiconductor layer;
a first electrode connected to the first semiconductor layer; and
a second electrode connected to the reflective layer.

13. The tiling display device of claim 12, wherein the reflective layer is in contact with an entirety of one surface of the second semiconductor layer.

14. A tiling display device comprising:
a lower substrate having a thin-film transistor disposed on an upper surface thereof;
a plurality of upper substrates respectively having light-emitting elements disposed on a lower surface thereof; and
a plurality of conductive adhesive members, respectively disposed between the plurality of upper substrates and the lower substrate to electrically connect the plurality of upper substrates and the lower substrate,
wherein the plurality of upper substrates are arranged in a matrix form in a first direction and a second direction perpendicular to the first direction, and are spaced apart from each other.

15. The tiling display device of claim 14, wherein the plurality of conductive adhesive members respectively bond the plurality of upper substrates and the lower substrate.

16. The tiling display device of claim 14, further comprising connection members disposed on the lower substrate, which electrically connects the light-emitting elements and the thin-film transistor to each other.

17. The tiling display device of claim 16, wherein the connection members are connection electrodes, connection wires or connection patterns.

18. The tiling display device of claim 14, further comprising a first filling material filled between the lower substrate and each of the plurality of upper substrates.

19. The tiling display device of claim 18, further comprising a second filling material filled between adjacent two upper substrates among the plurality of upper substrates.

20. The tiling display device of claim 18, wherein the first filling material includes a resin with relatively high viscosity and low flowability.

21. The tiling display device of claim 19, wherein the second filling material includes a resin with relatively high viscosity and low flowability.

22. The tiling display device of claim 18, wherein the first filling material has a first refractive index and a first light transmittance, and the second filling material has a second refractive index equal to the first refractive index and a second light transmittance equal to the first light transmittance.
